(19) United States
(12) Patent Application Publication
(10) Pub. No.: US 2026/0150414 A1
(43) Pub. Date: May 28, 2026

(54) SOLAR CELL AND PREPARATION METHOD THEREFOR

(71) Applicant: Contemporary Amperex Technology (Hong Kong) Limited, Hong Kong (CN)

(72) Inventors: Wenming GUO, Ningde (CN); Changsong CHEN, Ningde (CN); Zhaohui LIU, Ningde (CN); Bao TU, Ningde (CN); Weifeng LIANG, Ningde (CN); Xiangguang KONG, Ningde (CN); Guodong CHEN, Ningde (CN); Yongsheng GUO, Ningde (CN)

(73) Assignee: Contemporary Amperex Technology (Hong Kong) Limited, Hong Kong (CN)

(21) Appl. No.: 18/939,337

(22) Filed: Nov. 6, 2024

Related U.S. Application Data
(63) Continuation of application No. PCT/CN2022/113293, filed on Aug. 18, 2022.

(51) Int. Cl. H10F 19/90; H10F 77/00; H10F 77/20

(52) U.S. Cl. CPC H10F 19/904; H10F 77/215; H10F 77/935

(57) ABSTRACT

This application relates to a solar cell and a preparation method therefor. The solar cell includes a plurality of subcells and a plurality of grid lines. The subcells are sequentially arranged in series in a first direction, each including a substrate and a first electrode that are stacked. The plurality of subcells include two first subcells and at least one second subcell located between the two first subcells. The first direction is perpendicular to a thickness direction of the solar cell. The plurality of grid lines are disposed on the first electrodes in a one-to-one correspondence mode. An area of orthographic projections of the grid lines on the first subcells corresponding thereto is greater than an area of an orthographic projection of the grid line on the second subcell corresponding thereto. The solar cell can improve a current-limiting phenomenon, thereby improving the conversion efficiency of the solar cell.

### CROSS REFERENCE TO RELATED APPLICATION

This application is a continuation of International Patent Application No. PCT/CN2022/113293, filed on Aug. 8, 2022, which is incorporated by reference in its entirety.

### TECHNICAL FIELD

This application relates to the technical field of solar cells, and in particular, to a solar cell and a preparation method therefor.

### BACKGROUND

Since a perovskite solar cell was first reported in 2009, it has been favored by researchers for its ultra-low material cost and solution preparation process. The energy conversion efficiency of the perovskite solar cell with a small area (less than 1 cm²) has been increased from initial 3.8% to 25.8%. As the research further develops, it is highly likely that the conversion efficiency of the perovskite solar cell will exceed that of a single crystalline silicon solar cell which is currently well developed. Among a new generation of photovoltaic technologies, a perovskite solar energy technology is likely to be the first to be industrialized.

Subcells inside the perovskite solar cell form a series structure after being subjected to P1, P2 and P3 scribing. Photoelectric output performance parameters (a current, a voltage, and a fill factor) of the perovskite solar cell depend on the characteristic of each subcell, so the design and structure of each subcell are critical to the performance of the perovskite solar cell. However, the subcells of the conventional perovskite solar cell have a current-limiting phenomenon due to factors such as equipment and a process, which reduces the conversion efficiency of the perovskite solar cell.

### SUMMARY

Based on this, this application provides a solar cell and a preparation method therefor. The solar cell can improve a current-limiting phenomenon, thereby improving the conversion efficiency of the solar cell.

According to a first aspect, this application provides a solar cell. The solar cell includes:
a plurality of subcells, sequentially arranged in series in a first direction, where each of the subcells includes a substrate and a first electrode that are stacked; the plurality of subcells include two first subcells and at least one second subcell, and the at least one second subcell is located between the two first subcells; and the first direction is perpendicular to a thickness direction of the solar cell; and
a plurality of grid lines, disposed on the first electrodes of the subcells in a one-to-one correspondence mode, where an area of orthographic projections of the grid lines corresponding to the first subcells on the first subcells is greater than an area of an orthographic projection of the grid line corresponding to the second subcell on the second subcell.

According to the foregoing solar cell, the area of the orthographic projections of the grid lines on the first subcells on the first subcells is greater than the area of the orthographic projection of the grid line on the second subcell on the second subcell. Because of this, a contact area between the grid lines on the first subcells and the first electrodes on the first subcells is greater than a contact area between the grid line on the second subcell and the first electrode on the second subcell. In this way, the grid lines on the first subcells may have a higher current collecting capacity than the grid line on the second subcell, thereby compensating for a low-output current caused by self-structures of the first subcells. This increases an output current on the first subcells, thus minimizing a difference between the output current of the first subcells and an output current of the second subcell, improving a current-limiting phenomenon caused by a mismatch between the output currents of the first subcells and the second subcell and improving the conversion efficiency of the solar cell.

In some embodiments, the plurality of grid lines include:
two first grid lines, where the first grid lines are disposed on the first electrodes of the first subcells; and each of the first grid lines includes a first bus and a plurality of first branch lines connected to the first bus, and the first branch lines are arranged on one side of the first bus at intervals; and
at least one second grid line, where the second grid line is disposed on the first electrode of the second subcell; and the second grid line includes a second bus and a plurality of second branch lines connected to the second bus, and the second branch lines are arranged on one side of the second bus at intervals.

In this way, the first grid lines are correspondingly disposed on the first subcells, the second grid line is correspondingly disposed on the second subcell, and by adjusting structures of the first grid lines and the second grid line, the first grid lines and the second grid line have different current collecting capacities.

In some embodiments, the number of the first branch lines in the first grid lines is greater than the number of the second branch lines in the second grid line; and

a distance between any two adjacent first branch lines in the first grid lines is less than a distance between any two adjacent second branch lines in the second grid line.

In this way, an arrangement density of the first branch lines on the first grid lines is greater than an arrangement density of the second branch lines on the second grid line, so that the first grid lines have a higher current collecting capacity than the second grid line.

In some embodiments, an area of an orthographic projection of each of the first branch lines on the corresponding first subcell is equal to an area of an orthographic projection of each of the second branch lines on the corresponding second subcell.

In this way, the first branch lines may have the same size as the second branch lines, thereby reducing the preparation difficulty of the grid lines.

In some embodiments, an area of an orthographic projection of each of the first branch lines on the corresponding first subcell is greater than an area of an orthographic projection of each of the second branch lines on the corresponding second subcell.

In this way, a contact area between the first branch lines and the first electrodes is greater than a contact area between the second branch lines and the first electrode, so that the first grid lines have a higher current collecting capacity than the second grid line.

In some embodiments, in the thickness direction of the solar cell, a thickness of each of the first branch lines is equal to a thickness of each of the second branch lines.

In this way, the preparation difficulty of the grid lines may be reduced.

In some embodiments, thicknesses of the first branch lines and thicknesses of the second branch lines are greater than or equal to 20 nm and less than or equal to 200 nm. Widths of the first branch lines and widths of the second branch lines are greater than or equal to 20 μm and less than or equal to 100 μm.

In this way, in a case that the grid lines have a good current collecting capacity, on the one hand, it may be ensured that the grid lines have small resistance, and on the other hand, it may be ensured that the subcells have high light transmissivity.

In some embodiments, the plurality of subcells further include two third subcells, the two third subcells are located between the two first subcells, and each second subcell is located between the two third subcells; and
an area of orthographic projections of the grid lines corresponding to the third subcells on the third subcells is greater than the area of the orthographic projection of the grid line corresponding to the second subcell on the second subcell and less than the area of the orthographic projections of the grid lines corresponding to the first subcells on the first subcells.

In this way, a current collecting capacity of the grid lines on the third subcells may be improved, thereby compensating for a low current caused by self-structures of the third subcells. This increases an output current on the third subcells, so that the output currents on the first subcells, the second subcell and the third subcells are matched to the maximum extent, which improves a current-limiting phenomenon and improves the conversion efficiency of the solar cell.

In some embodiments, each of the subcells further includes a second electrode, a first charge transport layer, a light absorption layer and a second charge transport layer that are stacked on the corresponding substrate. The first electrode is disposed on a side of the second charge transport layer facing away from the substrate, and the corresponding grid line is disposed on a side of the first electrode facing away from the substrate. In this way, the structure of the solar cell may be more optimized, which reduces the preparation difficulty and has the high conversion efficiency.

In some embodiments, the light absorption layers include perovskite layers. In this way, such grid line structures may be applied to a perovskite cell to improve the conversion efficiency of the perovskite solar cell.

In some embodiments, extension lines are disposed in the subcells; and one end of each of the extension lines is connected to the grid line on the corresponding subcell, and the other end of each of the extension lines is connected to the second electrode of the adjacent subcell. In this way, the adjacent subcells may be connected in series through the extension lines.

According to a second aspect, this application provides a preparation method for a solar cell. The preparation method includes:
forming a first electrode on a substrate; and
forming a plurality of grid lines on the first electrode, and forming a plurality of subcells. The plurality of subcells are sequentially arranged in series in a first direction. The plurality of subcells include two first subcells and at least one second subcell, and the at least one second subcell is located between the two first subcells. The grid lines correspond to the subcells one to one, and an area of orthographic projections of the grid lines corresponding to the first subcells on the first subcells is greater than an area of an orthographic projection of the grid line corresponding to the second subcell on the second subcell The first direction is perpendicular to a thickness direction of the solar cell.

According to the foregoing preparation method for the solar cell, the area of the orthographic projections of the grid lines on the first subcells on the first subcells is greater than the area of the orthographic projection of the grid line on the second subcell on the second subcell. Because of this, a contact area between the grid lines on the first subcells and the first electrodes on the first subcells is greater than a contact area between the grid line on the second subcell and the first electrode on the second subcell. In this way, the grid lines on the first subcells may have a higher current collecting capacity than the grid line on the second subcell, thereby compensating for a low-output current caused by self-structures of the first subcells. This increases an output current on the first subcells, thus minimizing a difference between the output current of the first subcells and an output current of the second subcell, improving a current-limiting phenomenon caused by a mismatch between the output currents of the first subcells and the second subcell and improving the conversion efficiency of the solar cell.

The above description is only an overview of the technical solutions of this application. In order to be able to more clearly understand the technical means of this application, the technical solutions may be implemented in accordance with the contents of the specification, and in order to make the above and other objectives, features and advantages of this application more apparent and understandable, the specific implementations of this application are thereby listed.

### BRIEF DESCRIPTION OF DRAWINGS

In order to illustrate the technical solutions of the embodiments of this application more clearly, the following will briefly introduce the drawings that are desired to be used in the embodiments of this application. Apparently, the drawings described below are merely some embodiments of this application, from which other drawings may be obtained by a person of ordinary skill in the art without creative work.

FIG. 1 is a schematic diagram of a local structure of a solar cell in the related art;

FIG. 2 is a schematic top view of a solar cell according to an embodiment of this application;

FIG. 3 is a schematic diagram of a sectional structure of the solar cell in FIG. 2;

FIG. 4 is a schematic top view of another solar cell according to an embodiment of this application;

FIG. 5 is a schematic top view of yet another solar cell according to an embodiment of this application;

FIG. 6 is a flow chart of a preparation method for a solar cell according to an embodiment of this application;

FIG. 7 is a schematic structural diagram after P1 etching in a preparation method for a solar cell according to an embodiment of this application;

FIG. 8 is a schematic structural diagram after P2 etching in a preparation method for a solar cell according to an embodiment of this application; and

FIG. 9 is a schematic structural diagram after grid line formation, in a preparation method for a solar cell according to an embodiment of this application.

### REFERENCE SIGNS:

1. Perovskite solar cell;
11. Glass base; 12. Conductive film; 13. Electron transport layer;
14. Perovskite light absorption layer; 15. Hole transport layer; 16. Metal layer;
2. Solar cell;
21. Subcell; 21a. First subcell; 21b. Second subcell; 21c. Third subcell;
211. Substrate; 212. First electrode; 213. Second electrode;
214. First charge transport layer; 215. Light absorption layer;
216. Second charge transport layer;
22. Grid line;
221. First grid line; 2211. First bus; 2212. First branch line;
222. Second grid line; 2221. Second bus; 2222. Second branch line;
223. Third grid line; 2231. Third bus; 2232. Third branch line; 224. Extension line;
231. First trench; 232. Second trench; and 233. Third trench.

### DETAILED DESCRIPTION

The following describes in detail the embodiments of the technical solutions of this application with reference to the accompanying drawings. The following embodiments are merely intended for a clearer description of the technical solutions of this application and therefore are used as just examples which do not constitute any limitation on the protection scope of this application.

Unless otherwise defined, all technical and scientific terms used herein shall have the same meanings as commonly understood by persons skilled in the art to which this application belongs. The terms used herein are intended to merely describe the specific embodiments rather than to limit this application. The terms “comprise”, “include”, and any other variations thereof in the specification, claims and brief description of drawings of this application are intended to cover non-exclusive inclusions.

In the description of the embodiments of this application, the technical terms “first”, “second”, and the like are merely used to distinguish between different objects, and shall not be construed as any indication or implication of relative importance or any implicit indication of the quantity, particular sequence or primary-secondary relationship of the technical features indicated. In the description of the embodiments of this application, “a plurality of” means two or more unless otherwise expressly and specifically defined.

In this specification, reference to “embodiment” means that specific features, structures or characteristics described with reference to the embodiment may be incorporated in at least one embodiment of this application. The word “embodiment” appearing in various positions in the specification does not necessarily refer to the same embodiment or an independent or alternative embodiment that is exclusive of other embodiments. It is explicitly or implicitly understood by persons skilled in the art that the embodiments described herein may be combined with other embodiments.

In the descriptions of the embodiments of this application, the term “and/or” describes only an association relationship for describing associated objects and represents that three relationships may exist. For example, A and/or B may represent: the following three cases: only A alone, both A and B, and only B alone. In addition, the character “/” in this specification generally indicates an “or” relationship between contextually associated objects.

In the description of the embodiments of this application, the term “a plurality of” refers to two or more (including two), similarly, “a plurality of groups” refers to two or more groups (including two groups), and “a plurality of pieces” refers to two or more pieces (including two pieces).

In the description of the embodiments of this application, the orientation or positional relationships indicated by the technical terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, “axial”, “radial”, “circumferential”, etc. are based on the orientation or positional relationships shown in the drawings, merely to facilitate the description of the embodiments of this application and simplify the description, and do not indicate or imply that the device or element referred to must have a particular orientation, be constructed and operated in a particular orientation, and thus should not be construed as limiting the embodiments of this application.

In the description of the embodiments of this application, unless otherwise expressly specified and limited, the technical terms “mounted”, “connected”, “connect”, “fixed” and the like are to be understood in a broad sense, for example, it may be a fixed connection, or a detachable connection, or an integral connection; it may also be a mechanical connection or an electrical connection; and it may be a direct connection or indirect connection through an intermediate medium, and may be the interior communication between two elements or the interaction relationship between two elements. For a person of ordinary skill in the art, the specific meaning of the above-mentioned terms in the embodiments of this application may be understood according to specific circumstances.

Since a perovskite solar cell was first reported in 2009, it has been favored by researchers for its ultra-low material cost and solution preparation process, and the energy conversion efficiency of the perovskite solar cell with a small area (less than 1 cm²) has been increased from initial 3.8% to 25.8%. As the research further develops, it is highly likely that the conversion efficiency of the perovskite solar cell will exceed that of a single crystalline silicon solar cell which is currently well developed. Among a new generation of photovoltaic technologies, a perovskite solar energy technology is likely to be the first to be industrialized.

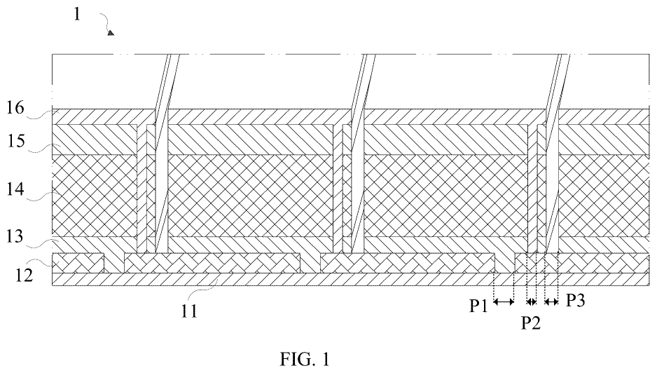

Specifically, as shown FIG. 1, a perovskite solar cell 1 includes a glass base 11, a conductive film 12, an electron transport layer 13, a perovskite light absorption layer 14, a hole transport layer 15 and a metal layer 16 that are stacked. Subcells inside the perovskite solar cell 1 form a series structure after being subjected to P1, P2 and P3 scribing. Photoelectric output performance parameters (a current, a voltage, and a fill factor) of the perovskite solar cell 1 depend on the characteristic of each subcell, so the design and structure of each subcell are critical to the performance of the perovskite solar cell 1.

Large coating equipment is typically used in a preparation process of the perovskite solar cell 1. Spatial distribution of process parameters such as a process gas, a temperature, an electromagnetic field, a plasma, a target material, and an evaporation source of the large coating equipment is non-uniform, leading to poor thickness uniformity of the perovskite light absorption layer 14. Generally, subcells at an edge region have a thinner perovskite light absorption layer 14 than subcells in a middle region, so that the subcells at the edge region have poorer performance than the subcells in the middle region, which is specifically shown as follows: the subcells at the edge region have an output current less than the subcells in the middle region. Thus, a mismatch between the output currents of the subcells at the edge region and the subcells in the middle region is caused, which produces a current-limiting phenomenon and reduces the conversion efficiency of the perovskite solar cell 1.

In order to alleviate the foregoing problems, the applicant found through research that by increasing a current collecting capacity of grid lines of the subcells at the edge region, a low-output current caused by self-structures of the subcells at the edge region can be compensated for, which increases an output current of the subcells at the edge region, thus minimizing a difference between the output current of the subcells at the edge region and an output current of the subcells in the middle region, improving the current-limiting phenomenon caused by the mismatch between the output currents of the subcells at the edge region and the subcells in the middle region and improving the conversion efficiency of the solar cell.

The solar cell disclosed in the embodiment of this application may be, but is not limited to, used in a transportation field, a communications/telecommunication field, an oil or marine field, and a household lamp field. The transportation field includes, for example, a navigation lamp, a traffic/railway signal lamp, a traffic warning/marker lamp, a Yuxiang street lamp, an aviation obstruction lamp, an expressway/railway radio telephone booth, and an unattended railway or highway maintenance squad power supply. The communications/telecommunication field includes, for example, a solar unattended microwave relay station, an optical cable maintenance station, a broadcast/communication/paging power system, a rural carrier telephone photovoltaic system, a small communicator, and a soldier GPS power supply. The oil or marine field includes, for example, an oil pipeline and reservoir gate cathodic protection solar power supply system, an oil drilling platform domestic and emergency power supply, and marine detection equipment. The household lamp field includes, for example, a yard lamp, a street lamp, a hand lamp, a camping lamp, a mountain climbing lamp, a fishing lamp, a black light lamp, a rubber tapping lamp, and an energy saving lamp.

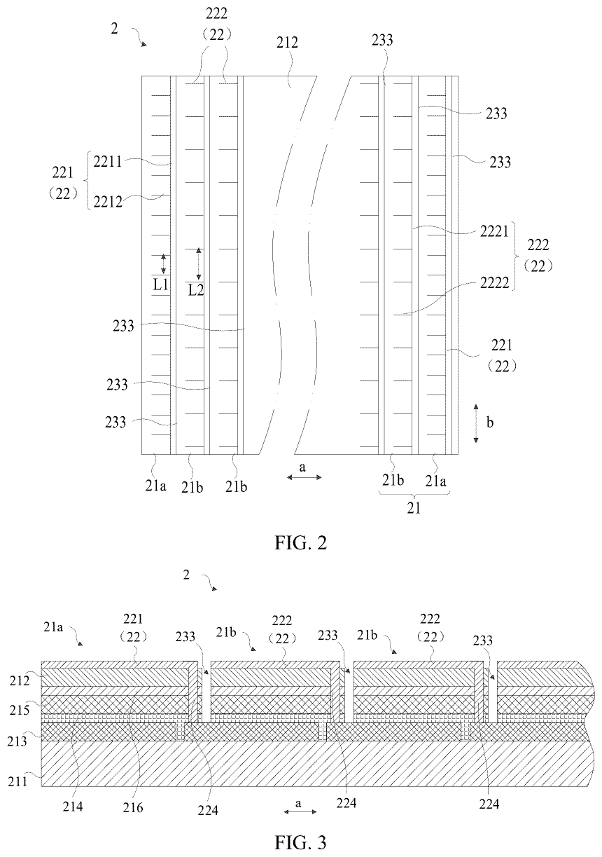

According to a first aspect, as shown in FIG. 2 and FIG. 3, an embodiment of this application provides a solar cell 2. The solar cell 2 includes a plurality of subcells 21 and a plurality of grid lines 22.

The plurality of subcells 21 are sequentially arranged in a first direction a, and mutually connected in series. The first direction a is perpendicular to a thickness direction of the solar cell 2. Each of the subcells 21 includes a substrate 211 and a first electrode 212 that are stacked, and the substrate 211 may be a glass base or a polyethylene glycol terephthalate (PET) base. The plurality of subcells 21 include two first subcells 21a and at least one second subcell 21b, and the at least one second subcell 21b is located between the two first subcells 21a. It may be understood that there may be a plurality of second subcells 21b, and the plurality of second subcells 21b are arranged between the two first subcells 21a at intervals.

The plurality of grid lines 22 are disposed on the first electrodes 212 of the subcells 21 in a one-to-one correspondence mode. An area of orthographic projections of the grid lines 22 on the first subcells 21a on the first electrodes 212 of the first subcells 21a is greater than an area of an orthographic projection of the grid line 22 on the second subcell 21b on the first electrode 212 of the second subcell 21b. The orthographic projections herein refer to:
orthographic projections of the grid lines 22 on the first electrodes 212 in the thickness direction of the solar cell 2.

The subcells 21 refer to minimum cell units that constitute the solar cell 2. The first subcells 21a refer to subcells 21 that are located at an edge region of the solar cell 2, and the second subcell 21b refers to a subcell 21 that is located at a non-edge region (middle region) of the solar cell 2. The grid lines 22 refer to conductive metals for collecting currents on the first electrodes 212. The grid lines 22 may be made of any one of metals such as gold, silver, copper, aluminum, nickel, zinc, tin and iron, or alloy including the foregoing metals. The first electrodes 212 refer to front electrodes or back electrodes that constitute the subcells 21. In the embodiment of this application, the first electrodes 212 refer to the back electrodes, and the grid lines 22 are disposed on the back electrodes.

The foregoing arrangement is equivalent to making a contact area between the grid lines 22 on the first subcells 21a and the first electrodes 212 on the first subcells 21a greater than a contact area between the grid line 22 on the second subcell 21b and the first electrode 212 on the second subcell 21b. It may be understood that the greater the contact area between the grid lines 22 and the first electrodes 212 is, the higher the capacity of the grid lines 22 to collect currents will be. Therefore, the grid lines 22 on the first subcells 21a may have a higher current collecting capacity than the grid line 22 on the second subcell 21b, thereby compensating for a low-output current caused by self-structures of the first subcells 21a, which increases an output current on the first subcells 21a, thus minimizing a difference between the output current of the first subcells 21a and an output current of the second subcell 21b, improving a current-limiting phenomenon caused by a mismatch between the output currents of the first subcells 21a and the second subcell 21b and improving the conversion efficiency of the solar cell 2.

In some embodiments, the grid lines 22 include two first grid lines 221 and at one second grid line 222. The first grid lines 221 are disposed on the first electrodes 212 of the first subcells 21a, and the second grid line 222 is disposed on the first electrode 212 of the second subcell 21b.

The first grid lines 221 refer to grid lines 22 that are disposed on the first electrodes 212 of the first subcells 21a. The second grid line 222 refers to a grid line 22 that is disposed on the first electrode 212 of the second subcell 21b.

In this way, the first grid lines 221 are correspondingly disposed on the first subcells 21a, the second grid line 222 is correspondingly disposed on the second subcell 21b, and by adjusting structures of the first grid lines 221 and the second grid line 222, the first grid lines 221 and the second grid line 222 have different current collecting capacities.

As an embodiment, each of the first grid lines 221 includes a first bus 2211 and a plurality of first branch lines 2212 connected to the first bus 2211, and the first branch lines 2212 are uniformly arranged on one side of the first bus 2211. The second grid line 222 includes a second bus 2221 and a plurality of second branch lines 2222 connected to the second bus 2221, and the second branch lines 2222 are uniformly arranged on one side of the second bus 2221.

The first buses 2211 are equivalent to “buses” on the first grid lines 221, and the first branch lines 2212 are equivalent to “branch lines” on the first grid lines 221. The second bus 2221 is equivalent to a “bus” on the second grid line 222, and the second branch lines 2222 are equivalent to “branch lines” on the second grid line 222. The first branch lines 2212 and the second branch lines 2222 are mainly configured to collect currents on the first electrodes 212. The first branch lines 2212 collect currents and then gather the currents to the first buses 2211, and the first buses 2211 transfer the currents out. The second branch lines 2222 collect currents and gather the currents to the second bus 2221, and the second bus 2221 transfers the currents out.

It may be understood that both sides of the first buses 2211 in the first direction a may be provided with the first branch lines 2212. Similarly, both sides of the second bus 2221 in the first direction a may be provided with the second branch lines 2222.

As an embodiment, both the first branch lines 2212 and the second branch lines 2222 extend in the first direction a, an extending direction of the first buses 2211 is perpendicular to an extending direction of the first branch lines 2212, and an extending direction of the second bus 2221 is perpendicular to an extending direction of the second branch lines 2222. In this way, on the one hand, the grid lines 22 may be relatively regular, and on the other hand, the preparation difficulty of the grid lines 22 may be reduced.

In some embodiments, the number of the first branch lines 2212 in the first grid lines 221 is greater than the number of the second branch lines 2222 in the second grid line 222. A distance L1 between any two adjacent first branch lines 2212 in the first grid lines 221 is less than a distance L2 between any two adjacent second branch lines 2222 in the second grid line 222.

In this way, it is equivalent to making an arrangement density of the first branch lines 2212 on the first grid lines 221 greater than an arrangement density of the second branch lines 2222 on the second grid line 222. Since there are more first branch lines 2212 on the first grid lines 221 and there is a less distance between the adjacent first branch lines 2212, the first grid lines 221 have a higher current collecting capacity than the second grid line 222.

In some embodiments, an area of an orthographic projection of each of the first branch lines 2212 on the first electrode 212 of the corresponding first subcell 21a is equal to an area of an orthographic projection of each of the second branch lines 2222 on the first electrode 212 of the corresponding second subcell 21b.

It may be understood that: a contact area between the first branch lines 2212 and the first electrodes 212 is equivalent to a contact area between the second branch lines 2222 and the first electrodes 212. In the embodiment of this application, the first branch lines 2212 and the second branch lines 2222 have the same shapes and sizes. In this way, the preparation difficulty of a mask may be reduced, thereby reducing the preparation difficulty of the grid lines 22. In another example, the first branch lines 2212 and the second branch lines 2222 have different shapes and sizes, and it also may be ensured that a contact area between the first branch lines 2212 and the first electrodes 212 is equal to a contact area between the second branch lines 2222 and the first electrodes 212.

In the embodiment of this application, since the first branch lines 2212 and the second branch lines 2222 have the same shapes and sizes, the number of the first branch lines 2212 in the first grid lines 221 may be greater than the number of the second branch lines 2222 in the second grid line 222, so that the first grid lines 221 have a higher current collecting capacity than the second grid line 222.

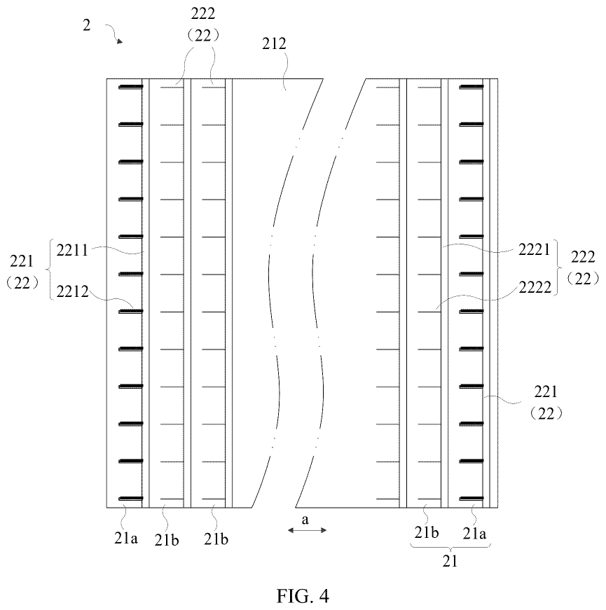

In some embodiments, as shown in FIG. 4, an area of an orthographic projection of each of the first branch lines 2212 on the first electrode 212 of the corresponding first subcell 21a is greater than an area of an orthographic projection of each of the second branch lines 2222 on the first electrode 212 of the corresponding second subcell 21b.

It may be understood that: a contact area between the first branch lines 2212 and the first electrodes 212 is greater than a contact area between the second branch lines 2222 and the first electrodes 212.

Specifically, the first branch lines 2212 may have a width equal to the second branch lines 2222 in a second direction b and have a length greater than the second branch lines 2222 in the first direction a; or the first branch lines 2212 may have a length equal to the second branch lines 2222 in the first direction a and have a width greater than the second branch line 2222 in the second direction b. The embodiment of this application does not limit the specific structures of the first branch lines 2212 and the second branch lines 2222.

In an example, when a contact area between the first branch lines 2212 and the corresponding first electrodes 212 is greater than a contact area between the second branch lines 2222 and the corresponding first electrode 212, the number of the first branch lines 2212 in the first grid lines 221 may be equal to the number of the second branch lines 2222 in the second grid line 222. In this way, in a case that the number of the first branch lines 2212 in the first grid lines 221 is equal to that of the second branch lines 2222 in the second grid line 222, the first grid lines 221 have a higher current collecting capacity than the second grid line 222.

In another example, when the contact area between the first branch lines 2212 and the corresponding first electrodes 212 is greater than the contact area between the second branch lines 2222 and the corresponding first electrode 212, the number of the first branch lines 2212 in the first grid lines 221 may also be greater than the number of the second branch lines 2222 in the second grid line 222. In this way, the first grid lines 221 may further have a higher current collecting capacity than the second grid line 222.

In yet another example, when the contact area between the first branch lines 2212 and the corresponding first electrodes 212 is greater than the contact area between the second branch lines 2222 and the corresponding first electrode 212, the number of the first branch lines 2212 in the first grid lines 221 may further be less than the number of the second branch lines in the second grid line 222. However, it is necessary to ensure that the contact area between the first grid lines 221 and the corresponding first electrodes 212 is greater than the contact area between the second grid line 222 and the corresponding first electrode 212, so that the first grid lines 221 have a higher current collecting capacity than the second grid line 222.

The contact area between the first branch lines 2212 and the first electrodes 212 is greater than the contact area between the second branch lines 2222 and the first electrode 212, so that the first branch lines 2212 in the first grid lines 221 may have a higher current collecting capacity than the second branch lines 2222 in the second grid line 222, and thus the first grid lines 221 have a higher current collecting capacity than the second grid line 222.

In some embodiments, in the thickness direction of the solar cell 2, a thickness of each of the first branch lines 2212 is equal to a thickness of each of the second branch lines 2222.

In this way, on the one hand, when the grid lines 22 are prepared, the first branch lines 2212 and the second branch lines 2222 with uniform thicknesses may be formed through a single process, thereby avoiding the first branch lines 2212 and the second branch lines 2222 from being formed through multiple processes respectively, and reducing the preparation difficulty of the grid lines; and on the other hand, in a case that the first branch lines 2212 and the second branch lines 2222 have the same shape, it may be ensured that the first branch lines 2212 and the second branch lines 2222 have the same resistance, so that the first branch lines 2212 and the second branch lines 2222 have the same current loss.

In some embodiments, thicknesses of the first branch lines 2212 and thicknesses of the second branch lines 2222 are greater than or equal to 20 nm and less than or equal to 200 nm. Widths of the first branch lines 2212 and widths of the second branch lines 2222 are greater than or equal to 20 μm and less than or equal to 100 μm.

Specifically, taking the first branch lines 2212 as an example, the thicknesses of the first branch lines 2212 refer to: distances between upper surfaces and lower surfaces of the first branch lines 2212 in the thickness direction of the solar cell 2. Exemplarily, the thicknesses of the first branch lines 2212 may be 20 nm, 30 nm, 50 nm, 100 nm, 150 nm, 175 nm, 190 nm, or 200 nm. The widths of the first branch lines 2212 refer to lengths of the first branch lines 2212 in the second direction b. The second direction b is perpendicular to the first direction a. Exemplarily, the widths of the first branch lines 2212 may be 20 μm, 30 μm, 50 μm, 60 μm, 80 μm, 90 μm, or 100 μm.

The thicknesses of the first branch lines 2212 and the second branch lines 2222 are within the foregoing range, in a case of ensuring that the solar cell 2 has a small thickness, the first branch lines 2212 and the second branch lines 2222 may have a certain structural strength, thereby avoiding the first branch lines 2212 and the second branch lines 2222 from being broken. The widths of the first branch lines 2212 and the second branch lines 2222 are within the foregoing range, on the one hand, it may be ensured that the first branch lines 2212 and the second branch lines 2222 have a good current collecting capacity, and on the other hand, it may be ensured that the subcells 21 have certain light transmissivity. At the same time, the above arrangement may make the first branch lines 2212 and the second branch lines 2222 have small resistance and less current losses, thereby improving the conversion efficiency of the solar cell 2.

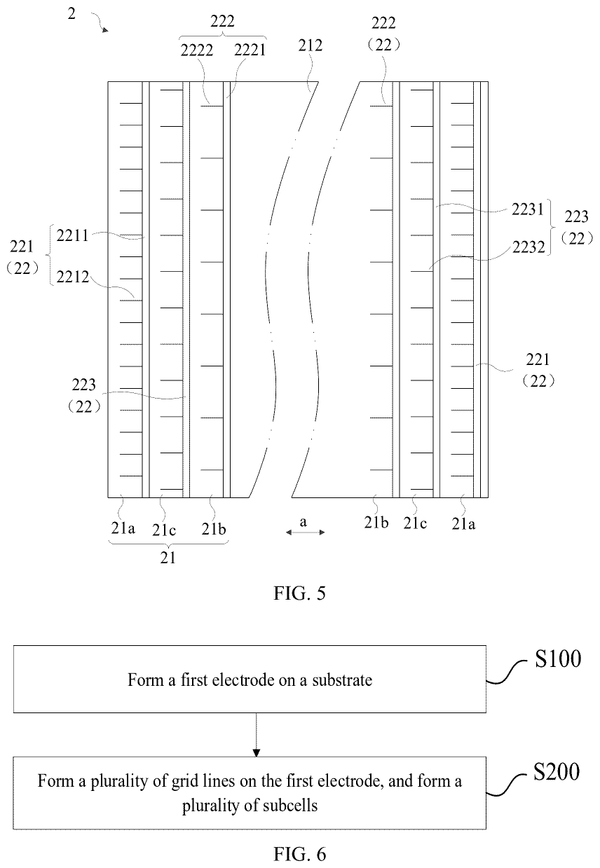

In some embodiments, as shown in FIG. 5, the plurality of subcells 21 further include two third subcells 21c, each second subcell 21b is located between the two third subcells 21c, and the two third subcells 21c are located between the two first subcells 21a.

It may be understood that: the first subcells 21a are located at the edge region of the solar cell 2, the second subcell 21b is located in the middle region of the solar cell 2, and the third subcells 21c are located at a transition region between the edge region and the middle region. Due to the influence of a preparation process, the performance sequence of the first subcells 21a, the second subcell 21b and the third subcells 21c is as follows: the second subcell 21b>the third subcells 21c>the first subcells 21a.

As an embodiment, an area of orthographic projections of the grid lines 22 corresponding to the third subcells 21c on the first electrodes 212 of the third subcells 21c is greater than the area of the orthographic projection of the grid line 22 corresponding to the second subcell 21b on the first electrode 212 of the second subcell 21b and less than the area of the orthographic projections of the grid lines 22 corresponding to the first subcells 21a on the first electrode 212 of the first subcells 21a.

As an embodiment, the grid lines 22 may include third grid lines 223, and the third grid lines 223 are disposed on the first electrodes 212 of the third subcells 21c. Each of the third grid lines 223 includes a third bus 2231 and a plurality of third branch lines 2232 connected to the third bus 2231, and the third branch lines 2232 are uniformly arranged on one side of the third bus 2231. A contact area between the third grid lines 223 and the first electrodes 212 on the third subcells 21c is greater than the contact area between the second grid line 222 and the first electrode on the second subcell 21b and less than the contact area between the first grid lines 221 and the first electrodes 212 on the first subcells 21a.

In this way, the current collecting capacity of the third grid lines 223 may be improved, thereby compensating for a low current caused by self-structures of the third subcells 21c, which increases an output current on the third subcells 21c, so that the output currents on the first subcells 21a, the second subcell 21b and the third subcells 21c are matched to the maximum extent, which improves a current-limiting phenomenon and improves the conversion efficiency of the solar cell 2.

It is hereby noted that the third grid lines 223 may be arranged in the same way as the first grid lines 221, which will not be described in detail in the embodiment of this application.

In some embodiments, as shown in FIG. 3, each of the subcells 21 further includes a second electrode 213, a first charge transport layer 214, a light absorption layer 215 and a second charge transport layer 216 that are stacked on the corresponding substrate 211, the first electrode 212 is disposed on a side of the second charge transport layer 216 facing away from the substrate 211, and the corresponding grid line 22 is disposed on a side of the first electrode 212 facing away from the substrate 211. In this way, the structure of the solar cell 2 may be more optimized, which reduces the preparation difficulty and has the high conversion efficiency.

The first electrodes 212 and the second electrodes 213 may be made of a conducting oxide, such as indium tin oxide (ITO), antimony tin oxide (AZO), boron-doped zinc oxide (BZO), and indium zinc oxide (IZO).

As an embodiment, the solar cell 2 is of a trans structure, the first charge transport layers 214 are hole transport layers, and the first charge transport layers 214 include all organic or inorganic materials that may be used as the hole transport layers. The second charge transport layers 216 are electron transport layers, and the second charge transport layers 216 include all organic or inorganic materials that may be used as the electron transport layers.

As an embodiment, the solar cell 2 is of a cis structure, the first charge transport layers 214 are electron transport layers, and the first charge transport layers 214 include all organic or inorganic materials that may be used as the electron transport layers. The second charge transport layers 216 are hole transport layers, and the second charge transport layers 216 include all organic or inorganic materials that may be used as the hole transport layers.

In some embodiments, the light absorption layers 215 include perovskite layers. In this way, such grid line 22 structures may be applied to perovskite cells so as to improve the conversion efficiency of the perovskite solar cell 2.

In some embodiments, as shown in FIG. 3, extension lines 224 are further disposed in the subcells 21. One end of each of the extension lines 224 is connected to the grid line 22 on the corresponding subcell 21, and the other end of each of the extension lines 224 is connected to the second electrode 213 of the subcell 21 adjacent to the corresponding subcell 21.

The extension lines 224 refer to conductive metals extending in the thickness direction of the solar cell 2, and the extension lines 224 may be considered as parts of the grid lines 22. Each of the extension lines 224 primarily serves to connect every two adjacent subcells 21 in series.

Through the foregoing arrangement in which the extension lines 224 connect the adjacent subcells 21 in series, the plurality of subcells 21 may be overall connected in series.

In some embodiments, as shown in FIG. 2, the grid lines 22 include two first grid lines 221 and at least one second grid line 222. The first grid lines 221 are disposed on the first electrodes 212 of the first subcells 21a, and the second grid line 222 is disposed on the first electrode 212 of the second subcell 21b. Each of the first grid lines 221 includes a first bus 2211 and a plurality of first branch lines 2212 connected to the first bus 2211, and the first branch lines 2212 are uniformly arranged on one side of the first bus 2211. The second grid line 222 includes a second bus 2221 and a plurality of second branch lines 2222 connected to the second bus 2221, and the second branch lines 2222 are uniformly arranged on one side of the second bus 2221.

The number of the first branch lines 2212 in the first grid lines 221 is greater than the number of the second branch lines 2222 in the second grid line 222. A distance L1 between any two adjacent first branch lines 2212 in the first grid lines 221 is less than a distance L2 between any two adjacent second branch lines 2222 in the second grid line 222. An area of an orthographic projection of each of the first branch lines 2212 on the first electrode 212 of the corresponding first subcell 21a is equal to an area of an orthographic projection of each of the second branch lines 2222 on the first electrode 212 of the corresponding second subcell 21b. Specifically, the first branch lines 2212 and the second branch lines 2222 have the same shapes, sizes and thicknesses.

In this way, on the one hand, it is equivalent to making an arrangement density of the first branch lines 2212 on the first grid lines 221 greater than an arrangement density of the second branch lines 2222 on the second grid line 222. Since there are more first branch lines 2212 on the first grid lines 221, the first grid lines 221 have a higher current collecting capacity than the second grid line 222. On the other hand, the “branch lines” of all the grid lines 22 may have the same sizes to facilitate preparation of the grid lines 22.

According to a second aspect, referring to FIG. 6 and in conjunction with FIG. 3, an embodiment of this application provides a preparation method for a solar cell. The method includes:

S100: Form a first electrode on a substrate. The substrate 211 may be a glass substrate or a PET substrate. The first electrode 212 may be made of a conducting oxide, such as indium tin oxide (ITO), antimony tin oxide (AZO), boron-doped zinc oxide (BZO), and indium zinc oxide (IZO). The first electrode 212 may be prepared through processes such as vacuum sputtering, reactive plasma sputtering coating, or atomic layer deposition.

S200: Form a plurality of grid lines on the first electrode, and form a plurality of subcells. The subcells 21a are sequentially arranged in a first direction a, and are mutually connected in series. The plurality of subcells 21a include two first subcells 21a and at least one second subcell 21b, and each second subcell 21b is located between the two first subcells 21a. The grid lines 22 correspond to the subcells 21a one to one. An area of orthographic projections of the grid lines 22 corresponding to the first subcells 21a on the first electrodes 212 of the first subcells 21a is greater than an area of an orthographic projection of the grid line 22 corresponding to the second subcell 21b on the first electrode 212 of the second subcell 21b. The first direction a is perpendicular to a thickness direction of the solar cell 2.

According to the foregoing preparation method for the solar cell, the area of the orthographic projections of the grid lines 22 on the first subcells 21a on the first subcells 21a is greater than the area of the orthographic projection of the grid line 22 on the second subcell 21b on the second subcell 21b, so that a contact area between the grid lines 22 on the first subcells 21a and the first electrodes 212 on the first subcells 21a is greater than a contact area between the grid line 22 on the second subcell 21b and the first electrode 212 on the second subcell 21b. In this way, the grid lines 22 on the first subcells 21a may have a higher current collecting capacity than the grid line 22 on the second subcell 21b, thereby compensating for a low-output current caused by self-structures of the first subcells 21a, which increases an output current on the first subcells 21a, thus minimizing a difference between the output current of the first subcells 21a and an output current of the second subcell 21b, improving a current-limiting phenomenon caused by a mismatch between the output currents of the first subcells 21a and the second subcell 21b and improving the conversion efficiency of the solar cell 2.

As an embodiment, before step S100 where a first electrode is formed on a substrate, the preparation method further includes:

S70: Form a second electrode on the substrate. The second electrode 213 may be made of a conductive oxide, such as indium tin oxide (ITO), antimony tin oxide (AZO), boron-doped zinc oxide (BZO), and indium zinc oxide (IZO).

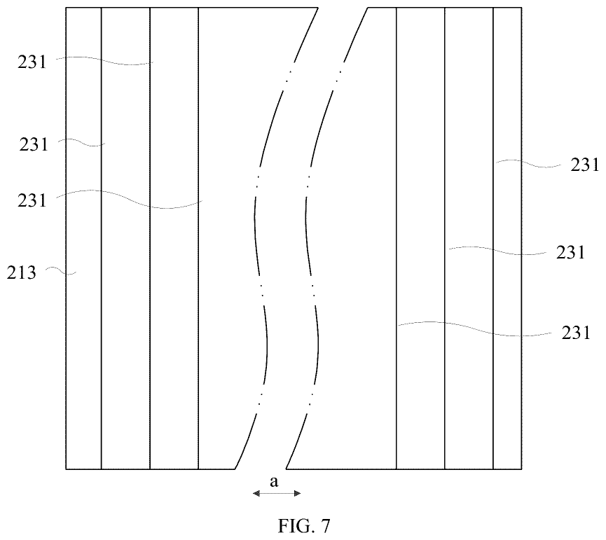

S80: Perform P1 scribing and etching on the second electrode to form a first trench. In the first direction a, scribing is performed every 6 μm to 10 mm, and a scribing width ranges from 10 μm to 80 μm. The structure after P1 scribing and etching is shown as FIG. 7. It is hereby noted that P1 scribing and etching may use laser etching or mechanical etching. Taking laser etching as an example, when P1 scribing and etching are performed, a laser device has a power of 3 W, a frequency of 145 KHz, and a rate of 1000 mm/s.

S90: Sequentially form a first charge transport layer, a light absorption layer and a second charge transport layer on the second electrode. Preparation methods for the first charge transport layer 214 and the second charge transport layer 216 may be vacuum sputtering, reactive plasma sputtering coating, vacuum thermal evaporation or wet coating, or the like. The light absorption layer 215 may be made of perovskite, and the light absorption layer 215 may be prepared using a wet coating process.

As an embodiment, step S200 where a plurality of grid lines are formed on the first electrode, and a plurality of subcells are formed specifically includes:

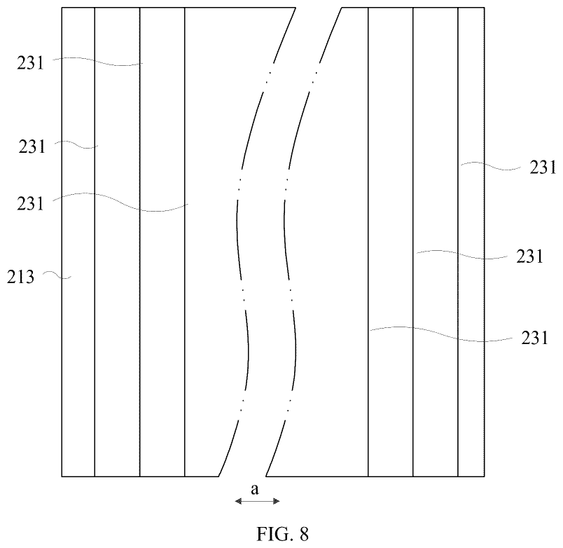

S210: Perform P2 scribing and etching on the first electrode to form a second trench. A P2 scribing width ranges from 50 μm to 150 μm. A distance between the second trench 232 and the first trench 231 in the first direction a ranges from 10 μm to 80 μm. The structure after P2 scribing and etching is as shown FIG. 8. It is hereby noted that P2 scribing and etching may use laser etching or mechanical etching. Taking laser etching as an example, when P2 scribing and etching are performed, a laser device has a power of 1 W, a frequency of 300 KHz, and a rate of 500 mm/s.

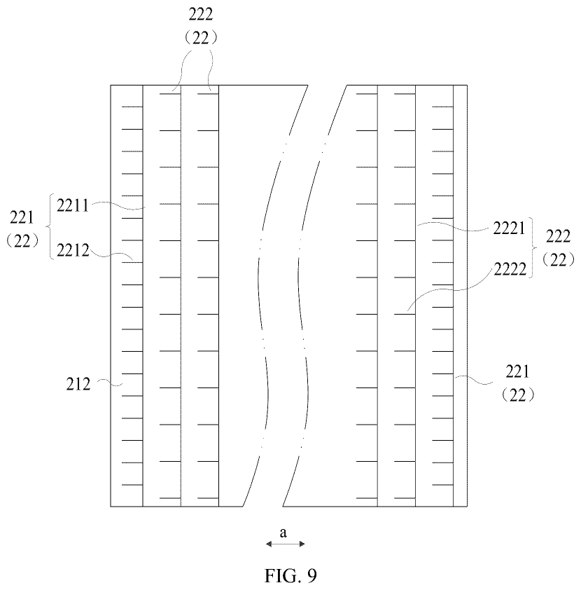

S220: Form the plurality of grid lines on the first electrode. The grid lines 22 may be made of any one of metals such as gold, silver, copper, aluminum, nickel, zinc, tin and iron, or alloy including the foregoing metals. The structure after the grid lines 22 are formed is as shown in FIG. 9. The grid lines 22 may be prepared through processes such as silk-screen printing, vacuum sputtering, or vacuum evaporation. Taking vacuum sputtering as an example, a sputtering power is 500 W, a working air pressure is 0.06 Pa, a target-substrate distance is 9 cm, and a deposition rate is 30 nm/s. Taking vacuum sputtering as an example, a working air pressure is 5×10⁻⁴ Pa, and a deposition rate is 3 nm/s. It may be understood that when the grid lines 22 are formed, the second trench 232 is filled with part of a metal, thereby electrically connecting the first electrode 212 to the second electrode 213.

S230: Perform P3 scribing and etching on the first electrode to form a third trench, thereby dividing the solar cell into a plurality of subcells. A P3 scribing width ranges from 20 μm to 200 μm, and a distance between the third trench 233 and the first trench 231 in the first direction a ranges from 0 μm to 200 μm. It is hereby noted that P3 scribing and etching may use laser etching or mechanical etching. Taking laser etching as an example, when P3 scribing and etching are performed, a laser device has a power of 1 W, a frequency of 600 KHz, and a rate of 600 mm/s. The structure after the third trench 233 is formed is as shown in FIG. 2.

It may be understood that, after step S230 where P3 scribing and etching are performed on the first electrode to form a third trench, thereby dividing the solar cell into a plurality of subcells, the solar cell 2 may further be subjected to processes such as edge clearing, testing, laminating and packaging to obtain a finished solar cell.

Finally, it should be noted that the foregoing embodiments are merely intended to describe the technical solutions of this application rather than to limit the technical solutions. Although this application is described in detail with reference to the foregoing embodiments, persons of ordinary skill in the art should understand that they may still make modifications to the technical solutions described in the foregoing examples or make equivalent replacements to some or all of the technical features thereof. However, these modifications or replacements do not make the essence of the corresponding technical solution depart from the scope of the technical solutions of the embodiments, and should all be covered in the scope of the claims and specification in this application. In particular, respective technical features mentioned in the respective embodiments may be combined in any manner as long as there is no structural conflict. This application is not limited to the specific embodiments disclosed in this specification, but includes all technical solutions falling within the scope of the claims.

What is claimed is:

1. A solar cell, comprising:
a plurality of subcells sequentially arranged in series in a first direction, wherein each of the subcells comprises a substrate and a first electrode that are stacked; and
a plurality of grid lines, disposed on the first electrodes of the subcells in a one-to-one correspondence mode;
wherein the plurality of subcells comprise two first subcells and at least one second subcell, and the at least one second subcell is located between the two first subcells; and the first direction is perpendicular to a thickness direction of the solar cell; and
wherein an area of orthographic projections of the grid lines corresponding to the first subcells on the first subcells is greater than an area of an orthographic projection of the grid line corresponding to the second subcell on the second subcell.

2. The solar cell according to claim 1, wherein the plurality of grid lines comprise:
two first grid lines, wherein the first grid lines are disposed on the first electrodes of the first subcells; and each of the first grid lines comprises a first bus and a plurality of first branch lines connected to the first bus, and the first branch lines are arranged on one side of the first bus at intervals; and
at least one second grid line, wherein the second grid line is disposed on the first electrode of the second subcell; and the second grid line comprises a second bus and a plurality of second branch lines connected to the second bus, and the second branch lines are arranged on one side of the second bus at intervals.

3. The solar cell according to claim 2, wherein
the number of the first branch lines in the first grid lines is greater than the number of the second branch lines in the second grid line; and
a distance between any two adjacent first branch lines in the first grid lines is less than a distance between any two adjacent second branch lines in the second grid line.

4. The solar cell according to claim 3, wherein an area of an orthographic projection of each of the first branch lines on the corresponding first subcell is equal to an area of an orthographic projection of each of the second branch lines on the corresponding second subcell.

5. The solar cell according to claim 2, wherein an area of an orthographic projection of each of the first branch lines on the corresponding first subcell is greater than an area of an orthographic projection of each of the second branch lines on the corresponding second subcell.

6. The solar cell according to claim 4, wherein in the thickness direction of the solar cell, a thickness of each of the first branch lines is equal to a thickness of each of the second branch lines.

7. The solar cell according to claim 2, wherein
thicknesses of the first branch lines and thicknesses of the second branch lines are greater than or equal to 20 nm and less than or equal to 200 nm; and
widths of the first branch lines and widths of the second branch lines are greater than or equal to 20 μm and less than or equal to 100 μm.

8. The solar cell according to claim 1, wherein
the plurality of subcells further comprise two third subcells, the two third subcells are located between the two first subcells, and each second subcell is located between the two third subcells; and
an area of orthographic projections of the grid lines corresponding to the third subcells on the third subcells is greater than the area of the orthographic projection of the grid line corresponding to the second subcell on the second subcell and less than the area of the orthographic projections of the grid lines corresponding to the first subcells on the first subcells.

9. The solar cell according to claim 1, wherein each of the subcells further comprises a second electrode, a first charge transport layer, a light absorption layer and a second charge transport layer that are stacked on the corresponding substrate, the first electrode is disposed on a side of the second charge transport layer facing away from the substrate, and the corresponding grid line is disposed on a side of the first electrode facing away from the substrate.

10. The solar cell according to claim 9, wherein the light absorption layers comprise perovskite layers.

11. The solar cell according to claim 9, wherein
extension lines are disposed in the subcells; and
one end of each of the extension lines is connected to the grid line on the corresponding subcell, and the other end of each of the extension lines is connected to the second electrode of the adjacent subcell.

12. A preparation method for a solar cell, comprising:
forming a first electrode on a substrate;
forming a plurality of grid lines on the first electrode; and
forming a plurality of subcells;
wherein
the plurality of subcells are sequentially arranged in series in a first direction;
the plurality of subcells comprise two first subcells and at least one second subcell, and the at least one second subcell is located between the two first subcells;
the grid lines correspond to the subcells one to one, and an area of orthographic projections of the grid lines corresponding to the first subcells on the first subcells is greater than an area of an orthographic projection of the grid line corresponding to the second subcell on the second subcell; and
the first direction is perpendicular to a thickness direction of the solar cell.
